(19) United States
(12) Patent Application Publication
(10) Pub. No.: US 2004/0198046 A1
(43) Pub. Date: Oct. 7, 2004

(54) Method for decreasing contact resistance of source/drain electrodes

(76) Inventors: Lee Yu-Chou, Taipei (TW); Hsu Min-Ching, Penghu City (TW)

Correspondence Address: PERKINS COIE LLP, PATENT-SEA, P.O. BOX 1247, SEATTLE, WA, 98111-1247, US

(21) Appl. No.: 10/405,827

(22) Filed: Apr. 1, 2003

(51) Int. Cl. H01L 21/302; H01L 21/461

(52) U.S. Cl. 438/689

(57) ABSTRACT

Ammonia gas plasma is introduced to surface of source and drain electrodes before formation of passivation layer on the source and drain electrodes to passivate the surface of the source and drain electrodes, to remove residues, particles, and oxide generated by antecedent etching step, and to saturate dangling bonds on surface of a channel region.

### BACKGROUND OF THE INVENTION

1. Field of the Invention

The present invention generally relates to a method for forming a thin film transistor, and more particularly to a method for decreasing contact resistance of source/drain electrodes.

2. Description of the Prior Art

Current liquid crystal display devices are using thin film transistors as switches. In fabrication of the thin film transistors, many thin films deposition steps, lithographic processes, and etching steps are involved. There are always cleaning processes after etching steps and before next thin film deposition.

One cleaning process is surface plasma treatment and to decrease contact resistance between indium tin oxide and source/drain electrodes. Panasonic has provided a helium plasma treatment to surfaces of silicon oxide, silicon nitride, amorphous silicon, n+ amorphous silicon, and single crystal silicon after etching step. Samsung Electronics provides a helium plasma treatment in dry etching chamber to isolated source and drain electrodes. Moreover, Mitsubishi Electronics uses N₂ and Helium mixture gas plasma to treat surface of an etched film to hydrophilic and nitride surface.

However, among these treating or cleaning methods, there are some drawbacks that conductivity of a conductive line can't be increased or contact resistance can't be decreased. Especially, RC delay is very critical to high resolution or large scaled panel, and panel circuits should be decreased less and less. Toward to the next generation of display panel, a method for surface treating by using plasma and also decreasing resistance should be provided.

### SUMMARY OF THE INVENTION

In accordance with the present invention, a method for decreasing contact resistance of source/drain electrodes and increasing conductivity of conductive lines is provided by introducing NH₃ gas plasma in chemical vapor deposition chamber. The NH₃ gas plasma is introduced before formation of the passivation layer by chemical vapor deposition method to passivate surface of the source/drain electrodes by using nitrogen radicals to decrease contact resistance, which is about 14% to 50%.

It is another object of this invention to decrease contact resistance between transparent electrode and source/drain electrodes without affecting electrical characteristic of thin film transistors to have less RC delay time.

It is a further object of this invention that this method can applied to large scaled or high resolution liquid crystal display panel.

In one embodiment, a method for decreasing contact resistance of a surface of thin film transistor for liquid crystal display device before formation of passivation layer is provided, wherein the thin film transistor comprises a gate electrode on a substrate, a gate insulating layer on the gate electrode, a semiconductor layer on the gate insulating layer and over the gate electrode, a source electrode and a drain electrode on the semiconductor layer. The method comprises a step of introducing ammonia gas plasma onto surface of the source electrode and the drain electrode to passivate thereof.

Another embodiment of this invention is provided that a method for forming a thin film transistor which comprises forming a gate electrode on a substrate.

Then, a gate insulating layer is formed on the gate electrode and substrate. An island semiconductor layer is formed on the gate insulating layer and over the gate electrode, and a source electrode and a drain electrode are formed on the island semiconductor layer with a channel region on the island semiconductor layer and between the source and drain electrodes. Next, ammonia gas plasma is introduced to surface of the source and drain electrodes to passivate thereof and to saturate dangling bonds on surface of the channel region. Then, a passivation layer is formed on the source and drain electrodes, and a contact windows is formed in the passivation layer to connect the drain electrode electrically.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a schematic representation of a thin film transistor on a substrate in accordance with this invention wherein particles, residues and oxide are formed on surface thereof after metal etching step;

FIG. 2 illustrates a schematic representation of an ammonia plasma treatment performed to the surface of the thin film transistor in accordance with this invention; and

FIG. 3 illustrates a schematic representation of a passivation layer formed on the thin film transistor in accordance with this invention.

### DESCRIPTION OF THE PREFERRED EMBODIMENT

Some sample embodiments of the present invention will now be described in greater detail. Nevertheless, it should be recognized that the present invention can be practiced in a wide range of other embodiments besides those explicitly described, and the scope of the present invention is expressly not limited except as specified in the accompanying claims.

In fabrication of thin film transistor liquid crystal display (TFT LCD) device, physical vapor deposition and etching step will generate particles, residues, and oxide on surface metal contact area of source and drain electrodes and channel region. Although a cleaning process is conducted, oxide on the surface of the source/drain electrodes can not be removed to increase resistance and influence conductivity of conductive line.

Therefore, this invention provides a NH₃ gas plasma treatment step to the metal contact surface of source/drain electrodes of the thin film transistors before formation of passivation layer by chemical vapor deposition to remove particles, residues, and oxide after etching step to decrease metal contact resistance.

Further, nitrogen radicals in NH₃ gas plasma will have passivation effect on surface of the channel in this invention, and a thin oxynitride layer is formed thereon after the following annealing process. Moreover, in the bombardment of etching step, dangling bonds and weak bonds of amorphous silicon are formed on surface of the channel. A stable structure site can be achieved by using hydrogen radicals to saturate the dangling bonds and weak bonds. The passivation and saturating effects not only decrease contact resistance of metal surface, but make thin film transistors and panel circuits more stable.

One embodiment of this invention provides that a method for decreasing contact resistance of source and drain electrodes in thin film transistor liquid crystal display device comprises a step of introducing gas plasma containing nitrogen and hydrogen to passivate surface of the source and drain electrodes before formation of a passivation layer on the thin film transistor. The gas in this invention is ammonia (NH₃), and this step is also called surface treatment. Dangling bonds on surface of a channel region between the source and drain electrodes are saturated at the surface treatment. Material of the passivation layer is silicon nitride, and the surface treatment step can be performed at a chamber of the step of forming the passivation layer.

The thin film transistor comprises a gate electrode on a substrate, a gate insulating layer on the gate electrode, an island semiconductor layer on the gate insulating layer and over the gate electrode, the source and drain electrodes on the island semiconductor layer, and a channel region on the island semiconductor layer and between the source electrode and the drain electrodes. The source electrode and drain electrode are formed by depositing a conductive layer on the island semiconductor layer and patterning to etch the conductive layer. The source electrode and drain electrode are formed by depositing a conductive layer on the island semiconductor layer and patterning to etch the conductive layer. Residues, particles, and oxide are therefore generated by the step of patterning to etch the conductive layer and can be removed by the surface treatment step of this invention.

This invention also provides a method for forming a thin film transistor which comprises forming a gate electrode on a substrate. Then, a gate insulating layer is formed on the gate electrode and substrate. An island semiconductor layer is formed on the gate insulating layer and over the gate electrode, and a source electrode and a drain electrode are formed on the island semiconductor layer with a channel region on the island semiconductor layer and between the source and drain electrodes. Next, ammonia gas plasma is introduced to surface of the source and drain electrodes to passivate thereof and to saturate dangling bonds on surface of the channel region. Then, a passivation layer is formed on the source and drain electrodes, and a contact windows is formed in the passivation layer to connect the drain electrode electrically. Material of the passivation layer is silicon nitride, and the step of introducing ammonia gas plasma is performed in the chamber of formation of the silicon nitride layer.

A preferred embodiment is disclosed in accordance with this invention.

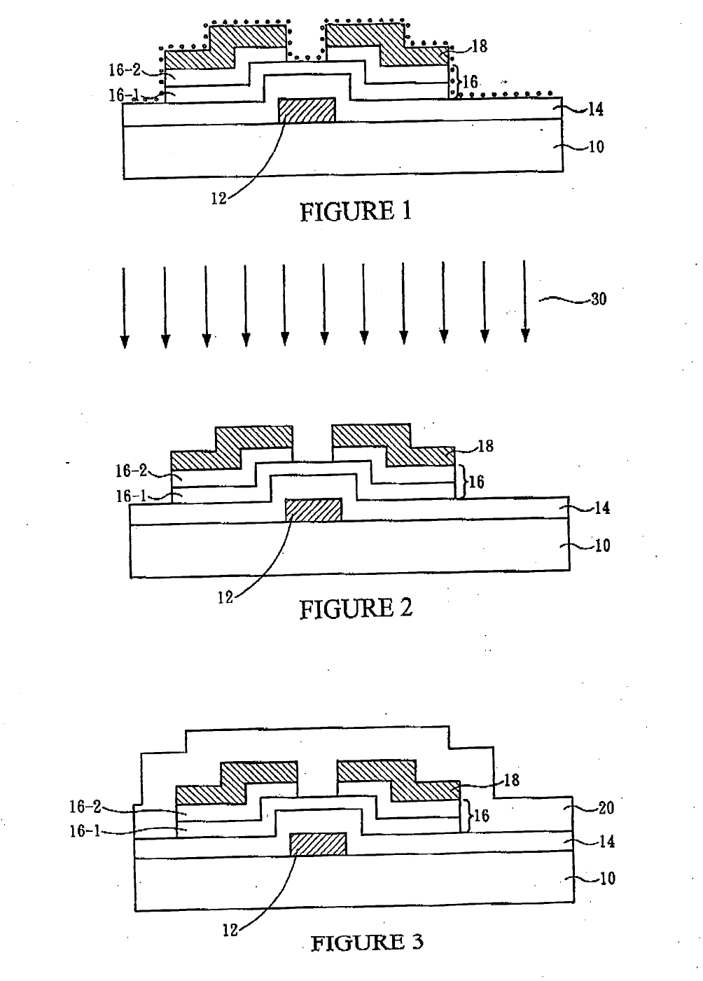

Referring to FIG. 1, a gate electrode layer 12 is formed on a substrate 10. When a back light source is used as light source for liquid crystal display device, the substrate 10 is transparent, such as glass or transparent plastic.

When a front light source is used as light source of the display device, the substrate 10 does not necessary be transparent. Material of the gate electrode layer 12 can be metal or any kind of conductive material, such as aluminum or aluminum alloy, molybdenum or molybdenum tungsten alloy, chromium or tantalum. Formation of the gate electrode layer 12 is to deposit a conductive layer by using sputtering method on the substrate 10, and lithographic and etching processes are performed to form gate electrode pattern on the predetermined position. When gate electrode pattern is formed on the substrate 10, gate line (not shown in Figures) is also formed on the substrate 10.

A blanket insulating layer 14 is formed on the substrate 10 to cover the gate electrode layer 12. The insulating layer 14, also called gate insulating layer, material of which is silicon nitride, is blanket deposited on the gate electrode layer 12 and substrate 10. The insulating layer 14 serves as gate dielectric layer of the thin film transistor and provides insulate isolation on the other area. Formation of the insulating layer 14 uses popular chemical vapor deposition method.

An island semiconductor layer 16 is formed on the insulating layer 14 and over the gate electrode layer 12. The semiconductor layer 16 primarily provides a channel region of the thin film transistor. In thin film transistor liquid crystal display device, channel region is above the gate electrode layer 12, and also named back channel region. The semiconductor layer 16 uses a composite layer within double layers, which is underneath amorphous silicon layer 16-1 and upper n+ amorphous silicon layer 16-2. The underneath amorphous silicon layer 16-1 provides channel region of the transistor, while the upper n+ amorphous silicon layer 16-2 serves as ohmic contact between metal and semiconductor to reduce resistant between metal source/drain and semiconductor layer.

A conductive layer 18, served as source and drain electrodes, are formed on the island semiconductor layer 16, and a thin film transistor is therefore formed. Material of this conductive layer 18 can be aluminum or aluminum alloy, molybdenum or molybdenum tungsten alloy, chromium or tantalum. Formation of the source and drain electrodes is to deposit a blanket conductive layer on the island semiconductor layer 16 and the gate insulating layer 14, and then a lithographic process is performed to remove a portion of conductive layer 18 to leave the source and drain electrodes. Due to this process comprises an etching step, which is a dry etching step, many particles, residues, and oxide are formed on surface of the source and drain electrodes, channel region between the source and drain electrodes and gate insulating layer 14. Further, a portion of the n+ amorphous silicon is removed and dangling bonds are formed at this etching step.

Referring to FIG. 2, a surface treatment is performed to surface of the thin film transistor. This surface treatment introduces gas plasma to remove particles, residues, and oxide on the surface of the thin film transistor wherein the gas containing hydrogen and nitrogen. A preferred gas is ammonia (NH₃). Ammonia gas plasma will be decomposed into hydrogen radicals and nitrogen radicals. Nitrogen radicals are used to remove particles, residues, and oxide on the surface of the thin film transistor, and to passivate the channel surface. More particularly, the channel surface after following annealing step will have a thin oxynitride passivation layer thereon. Hydrogen radicals are used to saturate dangling bonds at surface of the n+ amorphous silicon layer 16-2.

This surface treatment step can be performed at a chamber of forming passivation layer, and a pre-depositing cleaning can be achieved perfect. In one embodiment, flow rate of the NH₃ gas is between about 2000 to 50000 SCCM, applied power is between about 500 to 1500 W, pressure in the chamber is between about 0.4 to 0.8 mabr, and duration of the treatment is about 3 to 10 second. This surface treatment will have no effect on electrical characteristic of thin film transistor, because thin film transistor has been fabricated before the surface treatment step. However, contact resistance between the source/drain electrodes and indium tin oxide film can be decreased to 3 Ω and decreased range is about 14% to 50% compared to prior plasma treatment. RC delay of the panel circuits can be further reduced such that this invention can be applied to next generation of large scaled or high resolution panel.

Referring to FIG. 3, a passivation layer 20 is deposited on the conductive layer 18 to cover the transistor. The passivation layer 20 can be silicon nitride and formed by chemical vapor deposition method. Then, another lithographic process and an etching step are performed to form contact windows for drain electrode and the terminals on the peripheral of display panel.

This invention has many advantages that surface of the source/drain electrodes of thin film transistors has passivation effect by nitrogen radicals from introducing NH₃ gas plasma thereto before formation of the passivation layer by chemical vapor deposition, such that contact resistance and of the source/drain electrodes can be decreased about 14% to 50% and conductivity of conductive line can be increased. Less RC delay can be achieved without influencing the electrical characteristic of thin film transistors, which means this invention can be applied to large scaled liquid crystal display panel or high resolution panel for such panels need less RC delay.

Although specific embodiments have been illustrated and described, it will be obvious to those skilled in the art that various modifications may be made without departing from what is intended to be limited solely by the appended claims.

What is claimed is:

1. A method for decreasing contact resistance of source and drain electrodes in thin film transistor liquid crystal display device, said method comprising a step of introducing gas plasma containing nitrogen and hydrogen to passivate surface of said source and drain electrodes before formation of a passivation layer on said thin film transistor.

2. The method according to claim 1, wherein said gas is NH₃.

3. The method according to claim 1, wherein said step of introducing said gas plasma is to saturate dangling bonds on surface of a channel region between said source and drain electrodes.

4. The method according to claim 3, wherein said thin film transistor comprises:
a gate electrode on a substrate;
a gate insulating layer on said gate electrode and said substrate;
an island semiconductor layer on said gate insulating layer and over said gate electrode;
said source and drain electrodes on said island semiconductor layer; and
said channel region on said island semiconductor layer and between said source electrode and said drain electrodes.

5. The method according to claim 4, wherein said source electrode and said drain electrode are formed by depositing a conductive layer on said island semiconductor layer and patterning to etch said conductive layer.

6. The method according to claim 5, wherein said step of introducing said gas plasma is to remove residues, particles, and oxide generated by said step of patterning to etch said conductive layer.

7. The method according to claim 1, wherein material of said passivation layer is silicon nitride.

8. The method according to claim 7, wherein said step of introducing said gas plasma is performed at a chamber of said step of forming said passivation layer.

9. The method according to claim 6, wherein said step of introducing said gas plasma is to saturate dangling bond on surface of said channel region.

10. A method for treating a surface of thin film transistor for liquid crystal display device before formation of passivation layer, said thin film transistor comprising a gate electrode on a substrate, a gate insulating layer on said gate electrode, an island semiconductor layer on said gate insulating layer and over said gate electrode, a source electrode and a drain electrode on said island semiconductor layer, said method comprising a step of introducing ammonia gas plasma onto surface of said source electrode and said drain electrode to passivate thereof.

11. The method according to claim 10, wherein said step of introducing said ammonia gas plasma to saturate dangling bond on surface of said channel region.

12. The method according to claim 11, wherein said source electrode and said drain electrode are formed by depositing a conductive layer on said island semiconductor layer and patterning to etch said conductive layer.

13. The method according to claim 12, wherein said step of introducing said gas plasma is to remove residues, particles, and oxide generated by said step of patterning to etch said conductive layer.

14. The method according to claim 10, wherein material of said passivation layer is silicon nitride.

15. The method according to claim 14, wherein said step of introducing said ammonia gas plasma is performed at a chamber of said step of forming said passivation layer.

16. A method for forming a thin film transistor, said method comprising:
providing a substrate with a gate electrode thereon;
forming a gate insulating layer on said gate electrode and said substrate;
forming an island semiconductor layer on said gate insulating layer and over said gate electrode and forming a source electrode and a drain electrode on said island semiconductor layer with a channel region on said island semiconductor layer and between said source electrode and said drain electrode;
introducing ammonia gas plasma onto surface of said source electrode and said drain electrode to passivate thereof and to saturate dangling bond on surface of said channel region;
forming a passivation layer on said source electrode and said drain electrode; and
forming a contact window in said passivation layer to connect said drain electrode electrically.

17. The method according to claim 16, wherein material of said passivation layer is silicon nitride.

18. The method according to claim 17, wherein said step of introducing said ammonia gas plasma is performed at a chamber of said step of forming said passivation layer.
